(19) United States
(12) Patent Application Publication
(10) Pub. No.: US 2026/0076259 A1
(43) Pub. Date: Mar. 12, 2026

(54) SEMICONDUCTOR DEVICE

(71) Applicant: Kioxia Corporation, Tokyo (JP)

(72) Inventor: Masayoshi HIGASHIZONO, Yokohama Kanagawa (JP)

(73) Assignee: Kioxia Corporation, Tokyo (JP)

(21) Appl. No.: 19/049,867

(22) Filed: Feb. 10, 2025

(30) Foreign Application Priority Data
Sep. 11, 2024 (JP) 2024-157806

(51) Int. Cl. H01L 25/07; H10B 80/00

(52) U.S. Cl. CPC H10W 90/00; H10B 80/00; H10W 90/24

(57) ABSTRACT

According to one embodiment, a semiconductor device includes a substrate including a first surface and a recess portion in the first surface. A first semiconductor chip is disposed on a bottom surface of the recess portion. A first insulating material is filled in the recess portion and covering at least one surface of the first semiconductor chip. At least one second semiconductor chip is stacked above the first semiconductor chip.

### CROSS-REFERENCE TO RELATED APPLICATION

This application is based upon and claims the benefit of priority from Japanese Patent Application No. 2024-157806, filed Sep. 11, 2024, the entire contents of which are incorporated herein by reference.

### FIELD

Embodiments described herein relate generally to a semiconductor device.

### BACKGROUND

In a semiconductor device such as a NAND flash memory, a plurality of semiconductor chips may be stacked on the same wiring substrate from the viewpoints of miniaturization and high speed. In this case, a film over die (FOD) structure where the plurality of semiconductor chips are bonded to each other using a die attach film (DAF) provided therebetween and stacked is known.

### DESCRIPTION OF THE DRAWINGS

FIG. 1 is a plan view illustrating a configuration example of a semiconductor device according to a first embodiment.

FIG. 2 is a cross-sectional view illustrating the configuration example of the semiconductor device according to the first embodiment.

FIG. 3 is a cross-sectional view illustrating an example of a method of manufacturing the semiconductor device according to the first embodiment

FIG. 4 is a cross-sectional view continued from FIG. 3 and illustrating the example of the method of manufacturing the semiconductor device.

FIG. 5 is a cross-sectional view continued from FIG. 4 and illustrating the example of the method of manufacturing the semiconductor device.

FIG. 6 is a cross-sectional view continued from FIG. 5 and illustrating the example of the method of manufacturing the semiconductor device.

FIG. 7 is a plan view illustrating a configuration example of a semiconductor device according to a second embodiment.

FIG. 8 is a cross-sectional view illustrating the configuration example of the semiconductor device according to the second embodiment.

FIG. 9 is a cross-sectional view illustrating the configuration example of the semiconductor device according to the second embodiment.

FIG. 10 is a cross-sectional view illustrating an example of a method of manufacturing the semiconductor device according to the second embodiment.

FIG. 11 is a cross-sectional view illustrating an example of the method of manufacturing the semiconductor device according to the second embodiment.

FIG. 12 is a plan view illustrating a configuration example of a semiconductor device according to a third embodiment.

FIG. 13 is a cross-sectional view illustrating the configuration example of the semiconductor device according to the third embodiment.

FIG. 14 is a cross-sectional view illustrating an example of a method of manufacturing a package of the semiconductor device according to the third embodiment.

FIG. 15 is a cross-sectional view continued from FIG. 14 and illustrating an example of the method of manufacturing the semiconductor device.

FIG. 16 is a cross-sectional view continued from FIG. 15 and illustrating the example of the method of manufacturing the semiconductor device.

FIG. 17 is a cross-sectional view continued from FIG. 16 and illustrating the example of the method of manufacturing the semiconductor device.

### DETAILED DESCRIPTION

Embodiments provide a semiconductor device having high reliability where unintended protrusion of a bonding material used for stacking a plurality of semiconductor chips is prevented.

In general, according to one embodiment, a semiconductor device includes a wiring substrate including a recess portion on a first surface. A first semiconductor chip is disposed on a bottom surface of the recess portion. A first insulating material is filled in the recess portion and provided around the first semiconductor chip. At least one second semiconductor chip is stacked above the first semiconductor chip.

Hereinafter, embodiments of the present disclosure will be described with reference to the drawings. The embodiments do not limit the present disclosure. The drawings are schematic or conceptual. In the specification and the drawings, the same elements are represented by the same reference numerals.

### First Embodiment

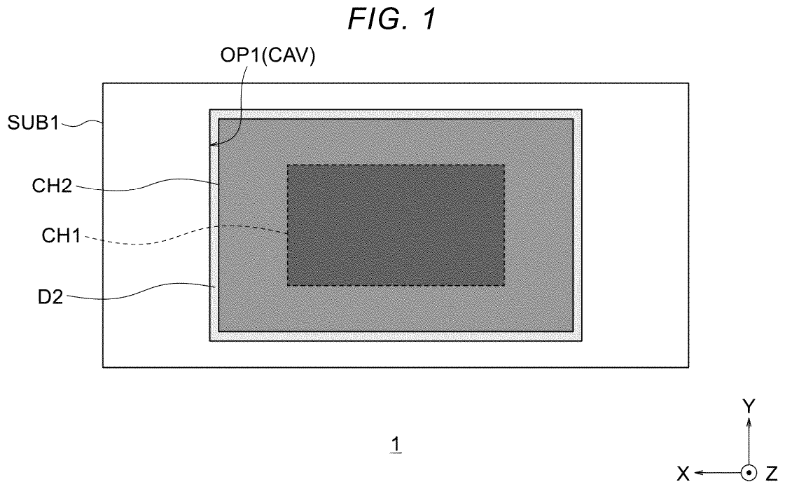

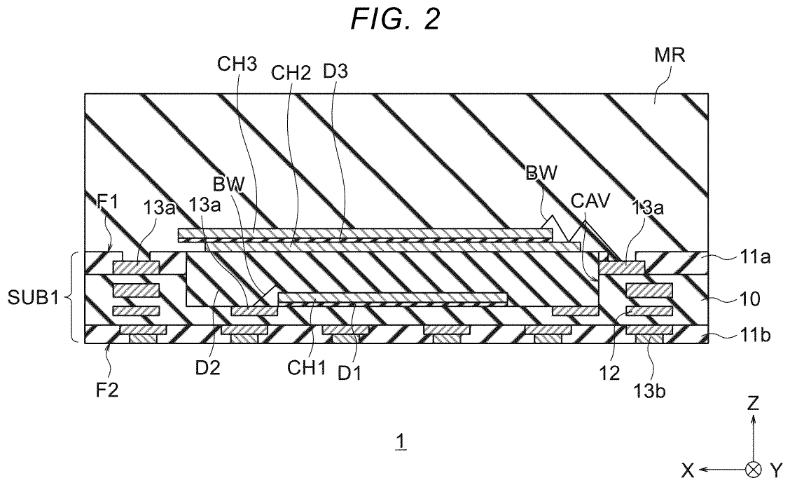

FIG. 1 is a plan view illustrating a configuration example of a semiconductor device 1 according to a first embodiment. FIG. 2 is a cross-sectional view illustrating the configuration example of the semiconductor device 1 according to the first embodiment.

As illustrated in FIG. 2, the semiconductor device 1 according to the present embodiment is a semiconductor package including a wiring substrate SUB1, semiconductor chips CH1 to CH3, insulating materials D1 to D3, a bonding wire BW, and a sealing resin MR.

The wiring substrate SUB1 includes a resin material 10, solder resists 11a and 11b, a wiring 12, and electrode pads 13a and 13b. The wiring substrate SUB1 is a substrate including a wiring layer configured with the wiring 12. The wiring substrate SUB1 electrically connects the semiconductor chips CH1 to CH3 to each other via the wiring 12, or electrically connects the semiconductor chips CH1 to CH3 and an external device to each other. The wiring substrate SUB1 includes a first surface F1 and a second surface F2 opposite to the first surface F1.

The resin material 10 is, for example, a glass epoxy resin. The resin material 10 is provided around the wiring 12 and electrically separates the wirings 12 from each other.

The solder resist 11a is provided on the first surface F1 side of the wiring substrate SUB1. The solder resist 11a exposes a part of a front surface of the electrode pad 13a.

The solder resist 11b is provided on the second surface F2 side of the wiring substrate SUB1. The solder resist 11b exposes a part of a front surface of the electrode pad 13b.

The wiring 12 is provided in the resin material 10 or in the solder resists 11a and 11b. The wiring 12 includes, for example, a metal material such as copper, tungsten, or aluminum.

The electrode pad 13a as the second electrode is provided on the first surface F1 side of the wiring substrate SUB1, and is exposed from the solder resist 11a. The electrode pad 13a functions as a bonding pad for connecting the bonding wire BW. A part of the electrode pad 13a is provided on a bottom portion of a recess portion CAV.

The electrode pad 13b is provided on the second surface F2 side of the wiring substrate SUB1, and is exposed from the solder resist 11b. The electrode pad 13b functions as a pad or a bump for electrical connection to an external device.

The wiring substrate SUB1 includes the recess portion CAV on the first surface F1 side. The recess portion CAV has a size that can accommodate the semiconductor chip CH1, and is filled with the insulating material D2. The recess portion CAV reaches the resin material 10 and is formed by depressing the resin material 10. The electrode pad 13a is provided on a bottom surface of the recess portion CAV. In addition, the semiconductor chip CH1 is disposed on the bottom surface of the recess portion CAV.

A depth of the recess portion CAV is more than a thickness of the semiconductor chip CH1. In addition, in a plan view seen from the first surface F1 (seen from the Z direction), as illustrated in FIG. 1, an outer edge of an opening OP1 of the recess portion CAV is outside of an outer edge of the semiconductor chip CH1. As a result, the semiconductor chip CH1 can be accommodated in the recess portion CAV, and the semiconductor chip CH1 can be disposed in the bottom surface of the recess portion CAV.

As illustrated in FIG. 1, in the plan view seen from the Z direction, the recess portion CAV is provided substantially at the center of the wiring substrate SUB1. However, a plane position of the recess portion CAV relative to the wiring substrate SUB1 is freely selected, and may be a position biased in an X direction and/or a Y direction.

The semiconductor chip CH1 is bonded to the bottom surface of the recess portion CAV using the insulating material D1. The semiconductor chip CH1 may be a controller chip that controls the semiconductor chips CH2 and CH3 as memory chips. The semiconductor chip CH1 is electrically connected to the electrode pad 13a provided on the bottom surface of the recess portion CAV through the bonding wire BW. The semiconductor chip CH1 is an example of the first semiconductor chip. The semiconductor chips CH2 and CH3 are examples of the second semiconductor chip.

A thickness of the semiconductor chip CH1 is less than the depth of the recess portion CAV. In addition, the outer edge of the semiconductor chip CH1 is smaller than the outer edge of the opening OP1 of the recess portion CAV. Accordingly, as described above, the semiconductor chip CH1 can be accommodated in the recess portion CAV.

The insulating material D1 is attached to a rear surface of the semiconductor chip CH1 in advance. In a die bonding process, the insulating material D1 is disposed on the bottom surface of the recess portion CAV together with the semiconductor chip CH1 and cured. As a result, the insulating material D1 bonds the semiconductor chip CH1 to the bottom surface of the recess portion CAV.

The insulating material D2 is filled in the recess portion CAV and is provided around the semiconductor chip CH1. As a result, the insulating material D2 protects the semiconductor chip CH1 and the bonding wire BW. In addition, the thickness of the cured insulating material D2 is substantially the same as the depth of the recess portion CAV. As a result, a front surface of the semiconductor chip CH2 disposed on the insulating material D2 is positioned above (+Z direction) the first surface F1.

The insulating material D2 is attached to a rear surface of the semiconductor chip CH2 in advance. In the die bonding process, the insulating material D2 is disposed to cover the semiconductor chip CH1 in the recess portion CAV together with the semiconductor chip CH2 and cured. As a result, the insulating material D2 can cover the semiconductor chip CH1 and the bonding wire BW and can bond the semiconductor chip CH2 to a region above the semiconductor chip CH1. In addition, the insulating material D2 can be filled in the recess portion CAV. In the plan view from the Z direction, the insulating material D2 has substantially the same size as the rear surface of the semiconductor chip CH2 before the curing but has substantially the same size as the opening OP1 of the recess portion CAV after the curing. The volume of the insulating material D2 is substantially the same as the capacity of the recess portion CAV.

The semiconductor chip CH2 is provided on the insulating material D2 and is stacked above the semiconductor chip CH1. The semiconductor chip CH2 is, for example, a memory chip including a memory cell array of a NAND flash memory. The semiconductor chip CH2 is electrically connected to the electrode pad 13a provided on the first surface F1 of the wiring substrate SUB1 via the bonding wire BW.

The outer edge of the semiconductor chip CH2 is somewhat smaller than the outer edge of the opening OP1 of the recess portion CAV. That is, in the plan view from the Z direction, the outer edge of the opening OP1 of the recess portion CAV is outside of the outer edge of the semiconductor chip CH2. Accordingly, as described above, the non-cured insulating material D2 attached to the semiconductor chip CH2 can be accommodated in the recess portion CAV. It is preferable that the sum of the volumes of the semiconductor chip CH1, the insulating material D1, the bonding wire BW connected to the semiconductor chip CH1, and the insulating material D2 is the same as the volume of the recess portion CAV. Therefore, the thickness of the non-cured insulating material D2 attached to the semiconductor chip CH2 is slightly more than the depth of the recess portion CAV. As a result, the volume of the insulating material D2 can be made substantially the same as the capacity of the recess portion CAV, and the recess portion CAV can be embedded with the insulating material D2.

The semiconductor chip CH3 is bonded to the front surface of the semiconductor chip CH2 through the insulating material D3. The semiconductor chip CH3 is, for example, a memory chip of a NAND flash memory as in the semiconductor chip CH2. The semiconductor chip CH3 is electrically connected to the electrode pad 13a provided on the first surface F1 of the wiring substrate SUB1 via the bonding wire BW.

The semiconductor chip CH3 is stacked to be shifted such that the electrode pad of the semiconductor chip CH2 is exposed above the semiconductor chip CH1. As a result, the semiconductor chip CH3 and the electrode pad 13a can be connected to each other through the bonding wire BW. Another semiconductor chip (not illustrated) may be stacked on the semiconductor chip CH3.

The insulating material D3 is attached to a rear surface of the semiconductor chip CH3 in advance. In the die bonding process, the insulating material D3 is disposed on the semiconductor chip CH2 together with the semiconductor chip CH3 and cured. As a result, the insulating material D3 bonds the semiconductor chip CH3 to the semiconductor chip CH2.

The sealing resin MR is provided on the first surface F1 of the wiring substrate SUB1, and covers the semiconductor chips CH2 and CH3 and the bonding wire BW. As a result, the sealing resin MR can protect the semiconductor chips CH2 and CH3 and the bonding wire BW.

The insulating materials D1 to D3 are, for example, insulating bonding materials such as a DAF. In the present embodiment, the insulating material D2 is embedded in the semiconductor chip CH1. That is, the thickness of the insulating material D2 is more than the thicknesses of the insulating materials D1 and D3.

In a FOD structure according to Comparative Example, a DAF attached to a rear surface of a semiconductor chip of a lower layer may flow onto the front surface from the rear surface of the semiconductor chip through a side surface during curing. In this case, a semiconductor chip of an upper layer stacked on the semiconductor chip may unintentionally float due to the DAF, or a bonding wire may come into contact with the DAF. Further, the DAF may protrude in a planar direction of a wiring substrate to reach an electrode pad on the wiring substrate. This protrusion may decrease the reliability of the semiconductor device.

Meanwhile, in the present embodiment, the recess portion CAV is provided in the wiring substrate SUB1, and the semiconductor chip CH1 is disposed in the recess portion CAV. The insulating material D2 covers the semiconductor chip CH1 and is filled in the recess portion CAV. The insulating material D2 has substantially the same volume as the capacity of the recess portion CAV. Therefore, the insulating material D2 does not bleed from the recess portion CAV during die bonding, and can be prevented from flowing onto the front surface through the side surface of the semiconductor chip CH2. Accordingly, the unintended floating of the semiconductor chip CH3 from the front surface of the semiconductor chip CH2 or unintended contact of the insulating material D2 with the bonding wire BW can be prevented.

Further, the recess portion CAV is filled with the insulating material D2 and thus does not have a gap. As a result, cracks formed when moisture penetrates into the gap can be prevented, and the reliability of the semiconductor device can be improved.

Next, a method of manufacturing the semiconductor device 1 according to the first embodiment will be described.

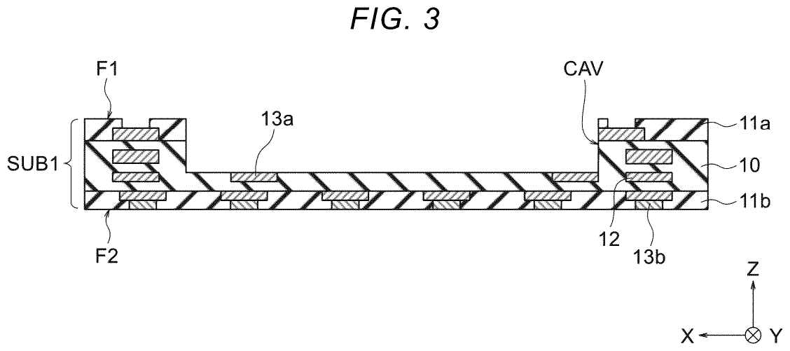

FIGS. 3 to 6 are cross-sectional views illustrating an example of the method of manufacturing the semiconductor device 1 according to the first embodiment.

As illustrated in FIG. 3, the wiring substrate SUB1 including the recess portion CAV on the first surface F1 is formed. The thickness of the wiring substrate SUB1 in the Z direction is, for example, about 195 μm in a region other than the recess portion CAV, and is, for example, about 90 μm in the region of the recess portion CAV. Accordingly, the depth of the recess portion CAV is, for example, about 105 μm.

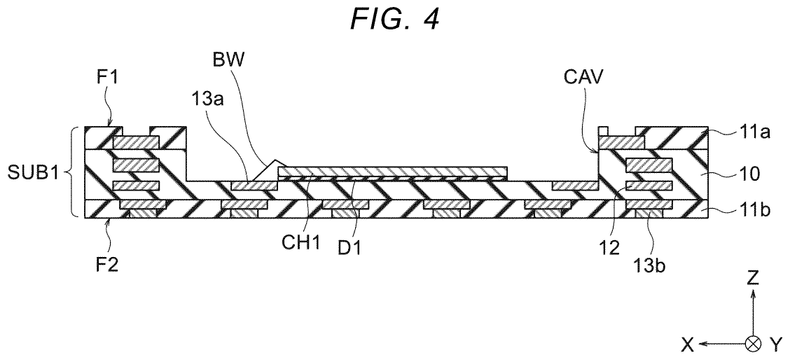

Next, as illustrated in FIG. 4, the semiconductor chip CH1 and the insulating material D1 are disposed on the bottom surface of the recess portion CAV. The insulating material D1 is attached to the rear surface of the semiconductor chip CH1 in advance. Accordingly, by curing the insulating material D1, the insulating material D1 bonds the semiconductor chip CH1 to the bottom portion of the recess portion CAV. Next, the electrode pad of the semiconductor chip CH1 and the electrode pad 13a on the bottom surface of the recess portion CAV are connected to each other through the bonding wire BW.

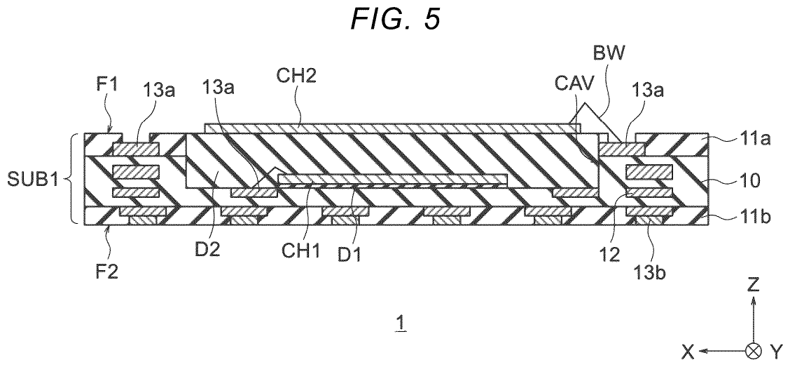

Next, as illustrated in FIG. 5, the semiconductor chip CH2 and the insulating material D2 are disposed to cover the semiconductor chip CH1 in the recess portion CAV. The insulating material D2 is attached to the rear surface of the semiconductor chip CH2 in advance. Accordingly, by curing the insulating material D2, the insulating material D2 bonds the semiconductor chip CH1 in the recess portion CAV and the semiconductor chip CH2 to each other. In addition, the insulating material D2 is filled in the recess portion CAV and supports the rear surface of the semiconductor chip CH2 substantially at the same height level as the solder resist 11a of the first surface F1. Next, the electrode pad of the semiconductor chip CH2 and the electrode pad 13a on the first surface F1 are connected to each other through the bonding wire BW.

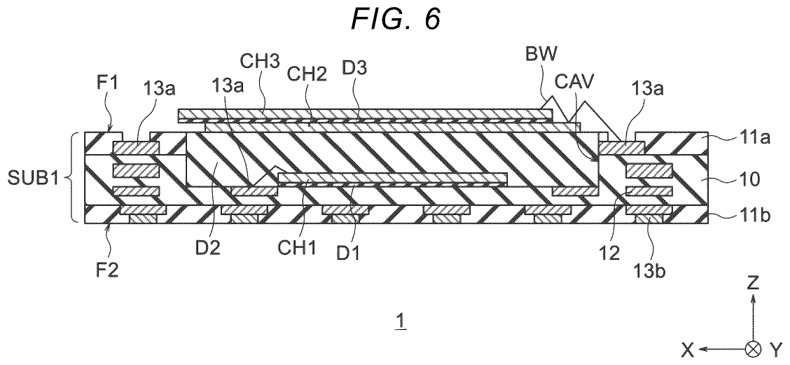

Next, as illustrated in FIG. 6, the semiconductor chip CH3 and the insulating material D3 are disposed on the semiconductor chip CH2. The insulating material D3 is attached to the rear surface of the semiconductor chip CH3 in advance. Accordingly, by curing the insulating material D3, the insulating material D3 bonds the semiconductor chip CH2 and the semiconductor chip CH3 to each other. Next, the electrode pad of the semiconductor chip CH3 and the electrode pad of the semiconductor chip CH2 are connected to each other through the bonding wire BW.

Next, optionally, another semiconductor chip is stacked on the semiconductor chip CH3 for wire bonding. Next, the sealing resin MR is formed on the first surface F1 to cover the stacked body of the semiconductor chips and the bonding wire BW. Furthermore, in order to increase the efficiency, the bonding process of the bonding wire BW may be performed batchwise after stacking all of the semiconductor chips.

As a result, the semiconductor device 1 according to the first embodiment illustrated in FIG. 2 is completed.

In the present embodiment, the insulating material D2 covers the semiconductor chip CH1 and is filled in the recess portion CAV. The insulating material D2 has substantially the same volume as the capacity of the recess portion CAV, and thus can be prevented from bleeding from the recess portion CAV during curing. Accordingly, the insulating material D2 does not flow onto the front surface of the semiconductor chip CH2, and the semiconductor chip CH3 can be prevented from floating from the front surface of the semiconductor chip CH2. In addition, the insulating material D2 can also be prevented from bleeding to the electrode pad 13a on the first surface F1.

### Second Embodiment

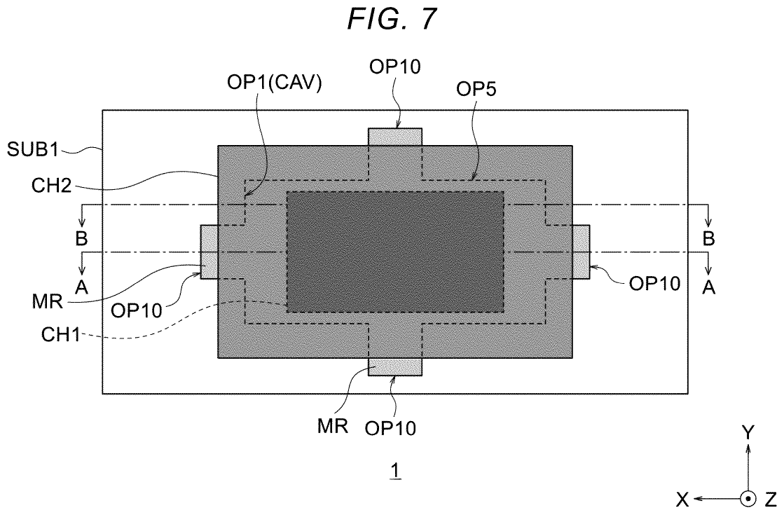

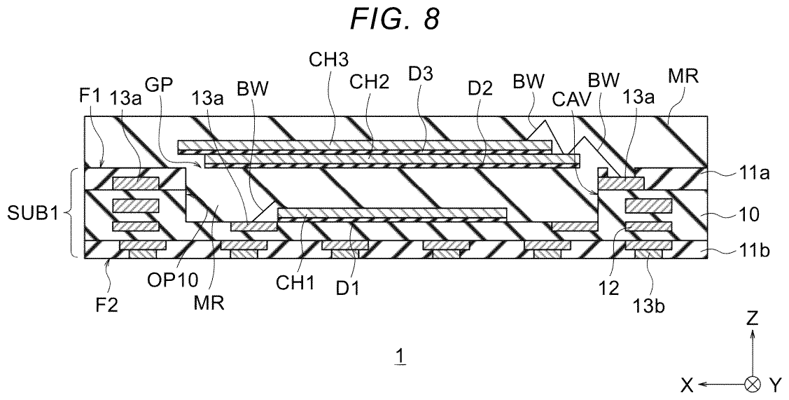

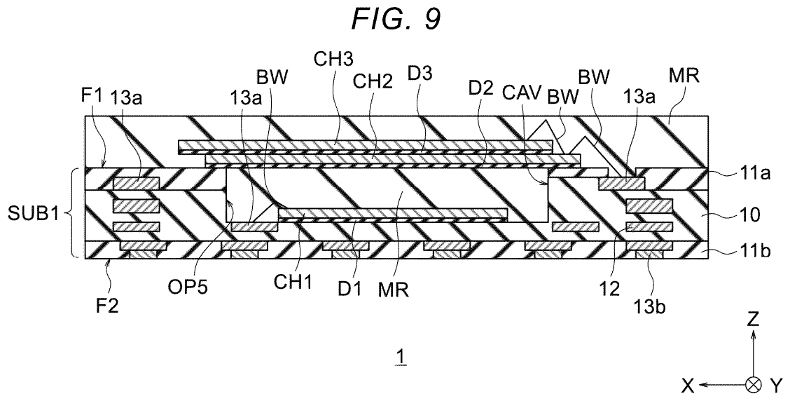

FIG. 7 is a plan view illustrating a configuration example of the semiconductor device 1 according to a second embodiment. FIGS. 8 and 9 are cross-sectional views illustrating the configuration example of the semiconductor device 1 according to the second embodiment. FIG. 8 illustrates a cross-section taken along line A-A of FIG. 7. FIG. 9 illustrates a cross-section taken along line B-B of FIG. 7.

As illustrated in FIG. 7, in the second embodiment, in the plan view seen from the Z direction, a planar shape of the opening OP1 of the recess portion CAV is different from that of the first embodiment. In addition, the second embodiment is different from the first embodiment, in that a material filled in the recess portion CAV is the sealing resin MR.

In the planar shape of the opening OP1, four protrusion portions OP10 that protrude in ±X directions and ±Y directions are provided on respective sides of an opening portion OP5 of a substantially rectangular shape. In the plan view seen from the Z direction, the outer edge of the opening portion OP5 is larger than and outside of the outer edge of the semiconductor chip CH1, and is smaller than and inside of the outer edge of the semiconductor chip CH2.

On the other hand, the protrusion portions OP10 protrude to the outside of the outer edge of the semiconductor chip CH2. Accordingly, as illustrated in FIG. 8, in an A-A cross-section of the region of the protrusion portions OP10, a gap GP is present between the semiconductor chip CH2 and the wiring substrate SUB1. The sealing resin MR penetrates from the gap GP into the recess portion CAV and is filled in the recess portion CAV.

In the plan view seen from the Z direction, the protrusion portions OP10 protrude substantially equally from the respective sides of the opening portion OP5. In addition, the protrusion portions OP10 have substantially the same width and length. As a result, the sealing resin MR can substantially uniformly penetrate into and is filled in the recess portion CAV.

An outer edge of the opening portion OP5 is smaller than and inside of the outer edge of the semiconductor chip CH2. Accordingly, as illustrated in FIG. 9, in a B-B cross-section of the region of the opening portion OP5, the semiconductor chip CH2 is bonded to the solder resist 11a of the wiring substrate SUB1 through the insulating material D2.

In this way, in the second embodiment, the planar shape of the opening OP1 of the recess portion CAV has the protrusion portions OP10, and the gap GP is formed between the semiconductor chip CH2 and the wiring substrate SUB1 as illustrated in FIG. 8. As a result, after stacking the semiconductor chips CH2 and CH3 above the semiconductor chip CH1, the sealing resin MR can be filled via the gap GP in a space formed between the semiconductor chip CH2 and the recess portion CAV. The sealing resin MR is also provided on the semiconductor chips CH2 and CH3 and formed on the first surface F1. Accordingly, the sealing resin MR is filled in the recess portion CAV and covers the periphery of the semiconductor chips CH2 and CH3 and the bonding wire BW. The sealing resin MR is integrally formed from the inside of the recess portion CAV to the region above the semiconductor chips CH2 and CH3, and is continuous in the gap GP.

In the second embodiment, the insulating material D2 may have the same thickness as the insulating materials D1 and D3. Accordingly, the recess portion CAV cannot be embedded with the insulating material D2. Accordingly, by providing the protrusion portions OP10, the sealing resin MR can penetrate from the gap GP into the recess portion CAV and can be filled in the recess portion CAV.

In addition, the opening portion OP5 is smaller than the outer edge of the semiconductor chip CH2. Therefore, as illustrated in FIG. 9, the wiring substrate SUB1 can support the semiconductor chips CH2 and CH3.

The rest of the configuration of the second embodiment may be the same as the configuration of the first embodiment. Accordingly, the second embodiment can obtain the same effects as the first embodiment.

Next, a method of manufacturing the semiconductor device 1 according to the second embodiment will be described.

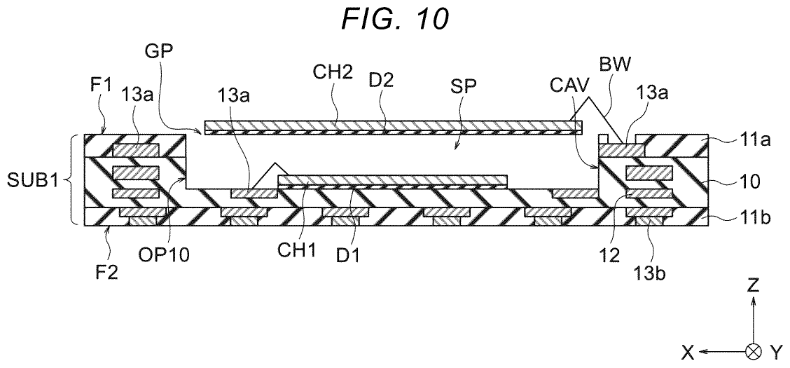

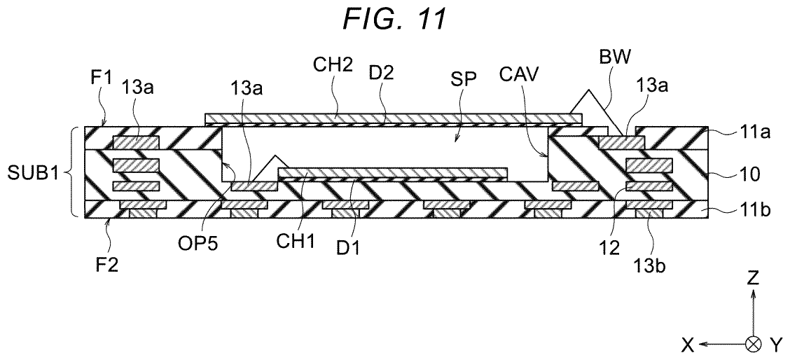

FIGS. 10 and 11 are cross-sectional views illustrating an example of the method of manufacturing the semiconductor device 1 according to the second embodiment. FIG. 10 corresponds to the cross-section taken along line A-A. FIG. 11 corresponds to the cross-section taken along line B-B.

The process described with reference to FIGS. 3 and 4 is performed. Although the planar shapes of the recess portion CAV are different, the cross-section at this time may be the same as the cross-section illustrated in FIGS. 3 and 4.

Next, as illustrated in FIGS. 10 and 11, the semiconductor chip CH2 is stacked on the wiring substrate SUB1. The insulating material D2 is attached to the rear surface of the semiconductor chip CH2 in advance. The thickness of the insulating material D2 is less than that of the first embodiment, and may be the same as that of the insulating materials D1 and D3. By curing the insulating material D2, the insulating material D2 bonds the semiconductor chip CH2 to the solder resist 11a of the wiring substrate SUB1.

Here, as illustrated in FIG. 10, in the region of the protrusion portions OP10, the gap GP is formed between the semiconductor chip CH2 and the wiring substrate SUB1. In addition, as illustrated in FIG. 11, in the region of the opening portion OP5, the semiconductor chip CH2 is bonded to the solder resist 11a of the wiring substrate SUB1 through the insulating material D2. A space SP is formed between the semiconductor chip CH2 and the wiring substrate SUB1.

Next, the electrode pad of the semiconductor chip CH2 and the electrode pad 13a on the first surface F1 are connected to each other through the bonding wire BW.

Next, as illustrated in FIGS. 8 and 9, the semiconductor chip CH3 and the insulating material D3 are disposed on the semiconductor chip CH2. The insulating material D3 is attached to the rear surface of the semiconductor chip CH3 in advance. Accordingly, by curing the insulating material D3, the insulating material D3 bonds the semiconductor chip CH2 and the semiconductor chip CH3 to each other. Next, the electrode pad of the semiconductor chip CH3 and the electrode pad of the semiconductor chip CH2 are connected to each other through the bonding wire BW.

Next, optionally, another semiconductor chip is stacked on the semiconductor chip CH3 for wire bonding. Furthermore, in order to increase the efficiency, the bonding process of the bonding wire BW may be performed batchwise after stacking all of the semiconductor chips.

Next, the sealing resin MR is formed on the first surface F1 to cover the stacked body of the semiconductor chips and the bonding wire BW. At this time, the sealing resin MR is also filled in the space SP via the gap GP. As a result, the structure illustrated in FIGS. 8 and 9 is obtained.

In the second embodiment, the sealing resin MR is filled in the recess portion CAV, and covers the semiconductor chips CH2 and CH3. Accordingly, the sealing resin MR is integrally formed on the inside of the recess portion CAV and the semiconductor chips CH2 and CH3. As a result, as the insulating material D2, the same type as the insulating materials D1 and D3 can be used, which leads to cost reduction.

The rest of the manufacturing process of the second embodiment may be the same as the manufacturing process of the first embodiment. Accordingly, the second embodiment can obtain the same effects as the first embodiment.

### Third Embodiment

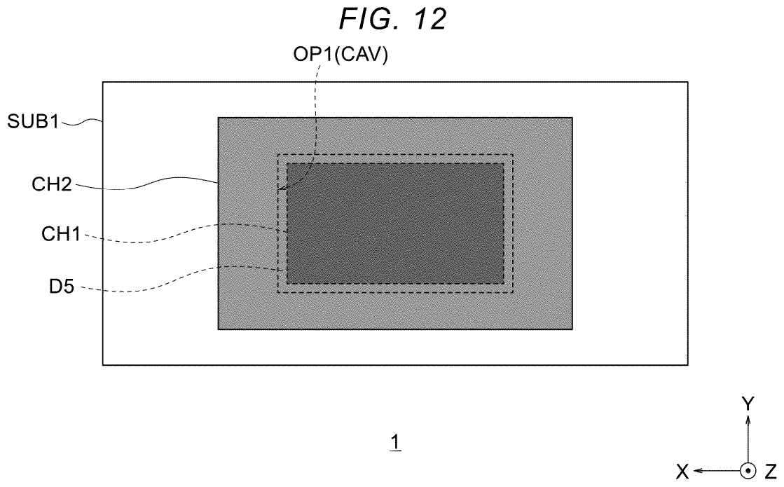

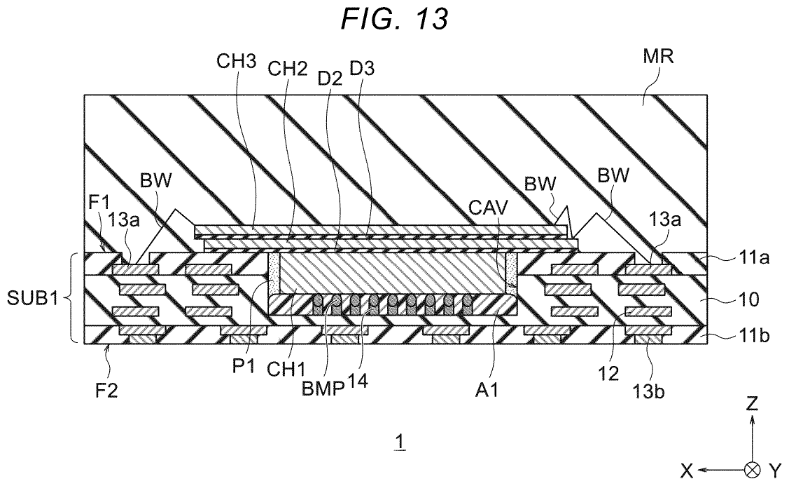

FIG. 12 is a plan view illustrating a configuration example of the semiconductor device 1 according to a third embodiment. FIG. 13 is a cross-sectional view illustrating the configuration example of the semiconductor device 1 according to the third embodiment.

As illustrated in FIG. 12, in the third embodiment, in the plan view seen from the Z direction, the outer edge of the opening OP1 of the recess portion CAV is smaller than and inside of the outer edge of the semiconductor chip CH2. Accordingly, the semiconductor chip CH2 is provided to cover the opening OP1 of the recess portion CAV, and is further provided on the wiring substrate SUB1.

In addition, as illustrated in FIG. 13, in the third embodiment, a plurality of metal bumps BMP as the first electrode are provided on the rear surface of the semiconductor chip CH1 facing the bottom surface of the recess portion CAV. The wiring substrate SUB1 includes a plurality of second electrodes 14 corresponding to the metal bumps BMP on the bottom surface of the recess portion CAV. As a result, the plurality of metal bumps BMP are connected to the plurality of second electrodes 14, respectively during die bonding. That is, the semiconductor chip CH1 is flip-chip bonded to the plurality of second electrodes 14 of the wiring substrate SUB1. As a result, the bonding wire BW does not need to be connected between the semiconductor chip CH1 and the wiring substrate SUB1.

A material A1 is provided around the metal bumps BMP and the second electrodes 14. The material A1 is, for example, an anisotropic conductive film (ACF), in which conductive particles are dispersed in a thermosetting resin. The material A1 has conductivity in a direction (Z direction) in which the semiconductor chip CH1 is bonded, and has insulating properties in the X and Y directions. That is, due to thermocompression bonding when the semiconductor chip CH1 is bonded to the bottom surface of the recess portion CAV, conductive particles in the material A1 come into contact with the metal bumps BMP and the second electrodes 14, and conductive paths are formed between the metal bumps BMP and the second electrodes 14. On the other hand, the conductive particles are dispersed in the thermosetting resin between the adjacent metal bumps BMP or between the adjacent second electrodes 14, and thus insulating properties are continuously maintained. As a result, electrical connection between the metal bumps BMP and the second electrodes 14 corresponding to each other is ensured, and electrical insulation between the adjacent metal bumps BMP or between the adjacent second electrodes 14 is maintained.

In addition, during die bonding to the inside of the recess portion CAV, the semiconductor chip CH1 has a thickness where the front surface thereof is substantially at the same height level as that of the first surface F1 of the wiring substrate SUB1. That is, the front surface of the semiconductor chip CH1 is preferably substantially flush with the first surface F1. As a result, the recess portion CAV does not need to be embedded with the insulating material D2. The insulating material D2 may have the same thickness as the insulating material D3.

An insulating material P1 is provided between a side surface of the semiconductor chip CH1 and an inner wall of the recess portion CAV. The insulating material P1 is, for example, a potting resin for embedding a gap. The potting resin is typically in a liquid state and is solidified by a heat treatment or an ultraviolet treatment. Furthermore, as the potting resin, a material having a relatively low thermal expansion coefficient is used. As a result, stress can be reduced, and cracks in the wiring substrate SUB1 and the like can be prevented. The semiconductor chip CH1 is fixed in the recess portion CAV by the material A1 and the insulating material P1. In addition, a gap in the recess portion CAV can be reduced, and the reliability of the semiconductor device 1 can be improved.

The semiconductor chip CH2 is stacked on the first surface F1 of the wiring substrate SUB1 and the semiconductor chip CH1. In addition, the semiconductor chip CH3 is stacked on the semiconductor chip CH2. Further, the other semiconductor chips may be stacked on the semiconductor chip CH3.

The rest of the configuration of the third embodiment may be the same as the configuration of the first embodiment. Accordingly, the third embodiment can obtain the same effects as the first embodiment.

Next, a method of manufacturing the semiconductor device 1 according to the third embodiment will be described.

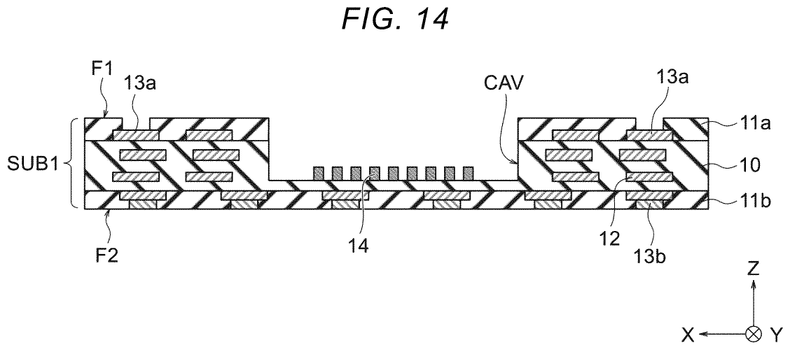

FIGS. 14 to 17 are cross-sectional views illustrating an example of the method of manufacturing the semiconductor device 1 according to the third embodiment.

As illustrated in FIG. 14, the plurality of second electrodes 14 are provided on the bottom surface of the recess portion CAV. The second electrode 14 is electrically connected to any of the wirings 12. The second electrode 14 protrudes from the bottom surface of the recess portion CAV. The rest of the configuration of the wiring substrate SUB1 according to the third embodiment may be the same as the configuration of the wiring substrate SUB1 according to the first embodiment.

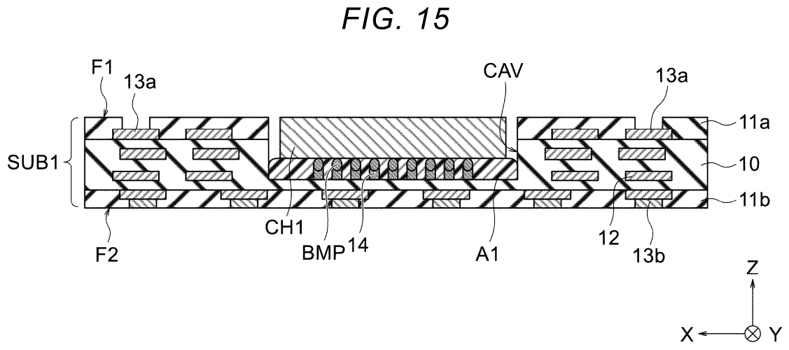

Next, as illustrated in FIG. 15, the semiconductor chip CH1 is disposed on the bottom surface of the recess portion CAV. The metal bumps BMP are provided on the rear surface of the semiconductor chip CH1. In addition, the material A1 is provided around the second electrode 14 in advance. Accordingly, by die bonding the semiconductor chip CH1 to the bottom portion of the recess portion CAV, the metal bumps BMP provided on the rear surface of the semiconductor chip CH1 are connected to the second electrodes 14 corresponding thereto. In addition, by curing the material A1, the material A1 bonds the bottom portion of the recess portion CAV and the semiconductor chip CH1 to each other.

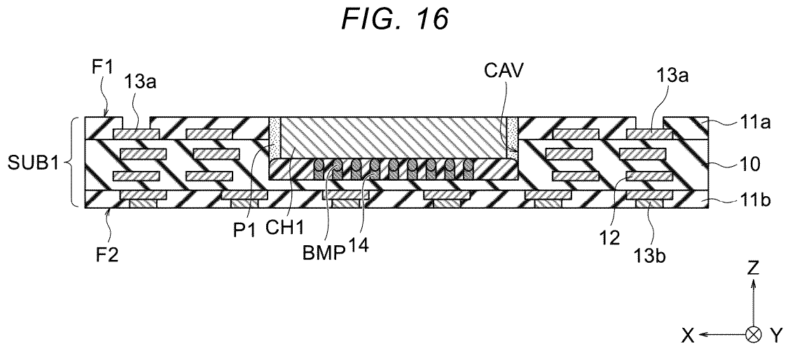

Next, as illustrated in FIG. 16, the insulating material P1 flows into a gap between the side surface of the semiconductor chip CH1 and a side wall of the recess portion CAV. Next, the insulating material P1 is solidified by a heat treatment or an ultraviolet treatment. As a result, the recess portion CAV is filled with the semiconductor chip CH1 and the insulating material P1.

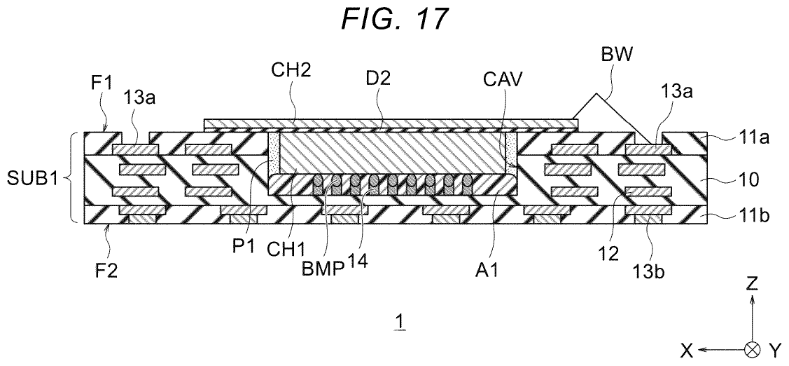

Next, as illustrated in FIG. 17, the semiconductor chip CH2 is stacked on the first surface F1 of the wiring substrate SUB1 and the semiconductor chip CH1. The insulating material D2 is attached to the rear surface of the semiconductor chip CH2 in advance. The insulating material D2 may have the same thickness as the insulating material D3. Accordingly, by curing the insulating material D2, the insulating material D2 bonds the solder resist 11a, the insulating material P1, and the semiconductor chip CH1 to the semiconductor chip CH2. Next, the electrode pad of the semiconductor chip CH2 and the electrode pad 13a on the first surface F1 are connected to each other through the bonding wire BW.

Next, as illustrated in FIG. 13, the semiconductor chip CH3 and the insulating material D3 are disposed on the semiconductor chip CH2. The insulating material D3 is attached to the rear surface of the semiconductor chip CH3 in advance. Accordingly, by curing the insulating material D3, the insulating material D3 bonds the semiconductor chip CH2 and the semiconductor chip CH3 to each other. Next, the electrode pad of the semiconductor chip CH3 and the electrode pad of the semiconductor chip CH2 are connected to each other through the bonding wire BW.

Next, optionally, another semiconductor chip is stacked on the semiconductor chip CH3 for wire bonding. Furthermore, in order to increase the efficiency, the bonding process of the bonding wire BW may be performed batchwise after stacking all of the semiconductor chips.

Next, the sealing resin MR is formed on the first surface F1 to cover the stacked body of the semiconductor chips and the bonding wire BW. As a result, the structure illustrated in FIG. 13 is obtained.

In the third embodiment, the semiconductor chip CH1 is flip-chip bonded to the inside of the recess portion CAV. Accordingly, in the recess portion CAV, the semiconductor chip CH1 and the second electrode 14 do not need to be wire-bonded to each other. Accordingly, the manufacturing of the semiconductor device 1 is facilitated.

In addition, the front surface of the semiconductor chip CH1 is substantially at the same height level as the first surface F1 of the wiring substrate SUB1. As a result, the semiconductor chip CH2 can be bonded to the semiconductor chip CH1 and the wiring substrate SUB1.

The rest of the manufacturing process of the third embodiment may be the same as the manufacturing process of the first embodiment. Accordingly, the third embodiment can obtain the same effects as the first embodiment.

Furthermore, the insulating material P1 may be present between the front surface of the semiconductor chip CH1 and the rear surface of the semiconductor chip CH2 or the insulating material D2. Even in this case, as long as the front surface of the insulating material P1 is substantially at the same height level as the first surface F1 of the wiring substrate SUB1, the semiconductor chip CH2 can be stacked above the semiconductor chip CH1.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. References to “approximately,” “about”, “substantially” or other terms of degree include variations of +/−10% from the given measurement, unit, or range unless explicitly indicated otherwise. The accompanying claims and their equivalents are intended to cover such forms or modifications as would fall within the scope and spirit of the disclosure.

What is claimed is:

1. A semiconductor device comprising:
a substrate including a first surface and a recess portion in the first surface;
a first semiconductor chip disposed on a bottom surface of the recess portion;
a first insulating material filled in the recess portion and covering at least one surface of the first semiconductor chip; and
at least one second semiconductor chip stacked above the first semiconductor chip.

2. The semiconductor device according to claim 1,
wherein a depth of the recess portion is more than a thickness of the first semiconductor chip.

3. The semiconductor device according to claim 1,
wherein a depth of the recess portion is substantially the same as a thickness of the first insulating material.

4. The semiconductor device according to claim 1,
wherein when seen in a plan view from a depth direction, an outer edge of an opening of the recess portion is outside of an outer edge of the first semiconductor chip.

5. The semiconductor device according to claim 1,
wherein the at least one second semiconductor chip is provided on the first insulating material.

6. The semiconductor device according to claim 5,
wherein when seen in a plan view from a depth direction, an outer edge of an opening of the recess portion is outside of an outer edge of the at least one second semiconductor chip.

7. The semiconductor device according to claim 1,
wherein the first insulating material covers a periphery of the at least one second semiconductor chip.

8. The semiconductor device according to claim 7,
wherein when seen in a plan view from a depth direction, the entirety of an outer edge of an opening of the recess portion is outside of an outer edge of the first semiconductor chip, a first part of the outer edge of the opening of the recess portion is outside of an outer edge of the at least one second semiconductor chip, and a second part of the outer edge of the opening of the recess portion is inside of the outer edge of the at least one second semiconductor chip.

9. The semiconductor device according to claim 1,
wherein the at least one second semiconductor chip is provided above the first semiconductor chip and the first surface of the substrate.

10. The semiconductor device according to claim 1,
wherein the at least one second semiconductor comprises a plurality of second semiconductor chips stacked above the first semiconductor chip.

11. The semiconductor device according to claim 1,
wherein the substrate includes a second electrode provided on the bottom surface of the recess portion, and the first semiconductor chip is electrically connected to the second electrode through a bonding wire.

12. The semiconductor device according to claim 1,
wherein the at least one second semiconductor chip is a memory chip including a memory cell array, and the first semiconductor chip is a controller chip including a control circuit that controls the memory chip.

13. A semiconductor device comprising:
a substrate including a first surface and a recess portion in the first surface;
a first semiconductor chip disposed on a bottom surface of the recess portion and including a front surface substantially flush with the first surface;
a first insulating material covering the front surface of the first semiconductor chip; and
at least one second semiconductor chip stacked above the first semiconductor chip.

14. The semiconductor device according to claim 13,
wherein the first semiconductor chip includes a plurality of first electrodes on a surface facing the bottom surface of the recess portion, and the plurality of first electrodes are connected to a plurality of second electrodes provided on the bottom surface of the recess portion, respectively.

15. The semiconductor device according to claim 13,
wherein the at least one second semiconductor chip is provided on the first insulating material.

16. The semiconductor device according to claim 13,
wherein the at least one second semiconductor chip is provided above the first semiconductor chip and the first surface of the substrate.

17. The semiconductor device according to claim 16,
wherein the at least one second semiconductor chip is disposed on the first insulating material, and
the first insulating material is disposed on the first semiconductor chip and the first surface of the substrate.

18. The semiconductor device according to claim 13,
wherein when seen in a plan view from a depth direction, an outer edge of an opening of the recess portion is outside of an outer edge of the first semiconductor chip.

19. The semiconductor device according to claim 13,
wherein the at least one second semiconductor comprises a plurality of second semiconductor chips stacked above the first semiconductor chip.

20. The semiconductor device according to claim 13,
wherein the at least one second semiconductor chip is a memory chip including a memory cell array, and the first semiconductor chip is a controller chip including a control circuit that controls the memory chip.
